(19) United States
(12) Patent Application Publication
(10) Pub. No.: US 2022/0346279 A1
(43) Pub. Date: Oct. 27, 2022

(54) TEMPERATURE CONTROLLING METHOD OF LIQUID COOLING DEVICE

(71) Applicant: AIC INC., Taoyuan City (TW)

(72) Inventors: Yen-Chih CHEN, Taoyuan City (TW); Hsih-Ting YOU, Taoyuan City (TW); Chi-Fu CHEN, Taoyuan City (TW)

(21) Appl. No.: 17/236,966

(22) Filed: Apr. 21, 2021

(51) Int. Cl. H05K 7/20

(52) U.S. Cl. CPC H05K 7/20381; H05K 7/20309; H05K 7/20318; H05K 7/20327

(57) ABSTRACT

A temperature controlling method of a liquid cooling device includes a providing step, a disposing step and a processing and controlling step. In the providing step: a microprocessor and multiple flexible micro sensors are provided. In the disposing step: the microprocessor is disposed on the liquid cooling device (including an evaporator, a condenser, a cold water tube, a hot water tube, a pumping motor and a cooling fan motor), and the micro sensors are separately disposed in the cold water tube and the hot water tube to directly contact with the liquid. In the processing and controlling step: the microprocessor receives data sensed in the cold water tube and the hot water tube by the micro sensors to calculate, and controls the pumping motor and the cooling fan motor to modulate an operating performance according to a calculated result.

### BACKGROUND

### Technical Field

The disclosure relates to a liquid cooling device, particularly to a temperature controlling method of a liquid cooling device.

### Related Art

A liquid cooling device utilizes cooling liquid (such as water or coolant) to perform liquid cooling to an electronic heat-generating component.

A liquid cooling device includes an evaporator, a condenser, a cold water tube, a hot water tube, a pump and a cooling fan, which are connected with each other. The evaporator is adhered on an electronic heat-generating component. The cooling fan is disposed on the condenser. Thus, the liquid is driven by the pump to circularly flow between the evaporator, the condenser and the cold and hot water tubes to remove heat from the electronic heat-generating component and the heated liquid is cooled down in the condenser. As a result, the electronic heat-generating component can be cooled down by the liquid.

An electronic heat-generating component does not keep at the same temperature. In fact, heat from an electronic heat-generating component may be varied high and low in temperature due to operation or other reasons. The related-art liquid cooling device may be provided with one or more temperature sensors for responsively controlling both the thrust of the pump and the rotation speed of the cooling fan when the heat generated from an electronic heat-generating component are varied.

However, the temperature sensor is disposed at some specific positions of the liquid cooling device, so the temperature sensed is not an actual temperature. This affects the accuracy of measurement, and further affects the sensitivity and the response time of sensing. Thus, it cannot be applied in electronic products requiring high accuracy, high sensitivity and short response time.

Further, in the temperature control of the related-art liquid cooling device, the temperature sensors are connected to a central processing unit (CPU) to use the CPU for additionally processing and controlling thrust of the pump and the rotation speed of the cooling fan. The temperature control can be implemented, but the installing and uninstalling of the liquid cooling device involve the CPU. It is troublesome and inconvenient.

### SUMMARY

An object of the disclosure is to provide a temperature controlling method of a liquid cooling device, which possesses high accuracy, high sensitivity and short response time to perform the temperature control accurately.

To accomplish the above object, the disclosure provides a temperature controlling method of a liquid cooling device used for cooling by a liquid, which includes the steps of: providing a microprocessor and multiple flexible micro sensors; disposing the microprocessor on the liquid cooling device, wherein the liquid cooling device comprises an evaporator, a condenser, a cold water tube, a hot water tube, a pumping motor and a cooling fan motor; and disposing each of the micro sensors in the cold water tube and the hot water tube respectively to directly contact with the liquid; and receiving, by the microprocessor, data sensed in the cold water tube and the hot water tube by the micro sensors to calculate, and controlling the pumping motor and the cooling fan motor to modulate an operating performance according to a calculated result.

In comparison with the related art, the disclosure has the effects of high accuracy, high sensitivity and short response time for performing the temperature control accurately.

In view of this, the inventors have devoted themselves to the above-mentioned related art, researched intensively and cooperated with the application of science to try to solve the above-mentioned problems. Finally, the disclosure which is reasonable and effective to overcome the above drawbacks is provided.

### BRIEF DESCRIPTION OF THE DRAWINGS

FIG. 1A is a flowchart of an embodiment of the temperature control method of the disclosure;

FIG. 1B is a flowchart of another embodiment of the temperature control method of the disclosure;

FIG. 2 is a block diagram of the another embodiment of the temperature control method of the disclosure;

FIG. 3 is a schematic view of the micro sensors disposed by the temperature control method of the disclosures;

FIG. 4 is a partially enlarged view of FIG. 3; and

FIG. 5 is a cross-sectional schematic view of the micro sensors disposed on an inner wall of the cold or hot water tube of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

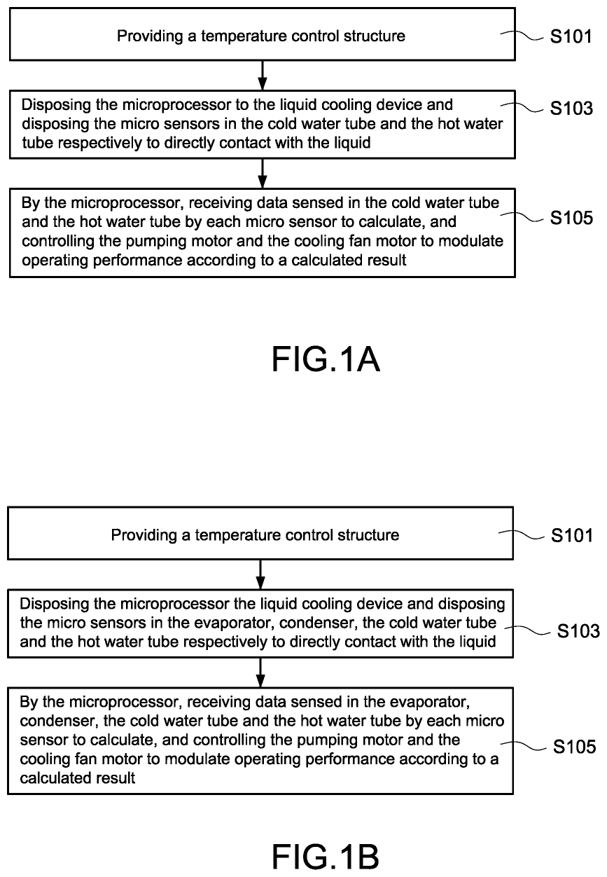

Please refer to FIGS. 1-4. The disclosure provides a temperature controlling method of a liquid cooling device, which is used for cooling electronic heat-generating components of various computers (such as a high-performance computer or server, etc.) by a liquid. The liquid cooling device includes an evaporator 51, a condenser 52, a cold water tube 53, a hot water tube 54, a pump (not shown in figures) and a cooling fan (not shown in figures). The pump has a pumping motor 55. The cooling fan has a cooling fan motor 56.

The temperature controlling method of the liquid cooling device of the disclosure includes a providing step S101, a disposing step S103 and a processing and controlling step S105.

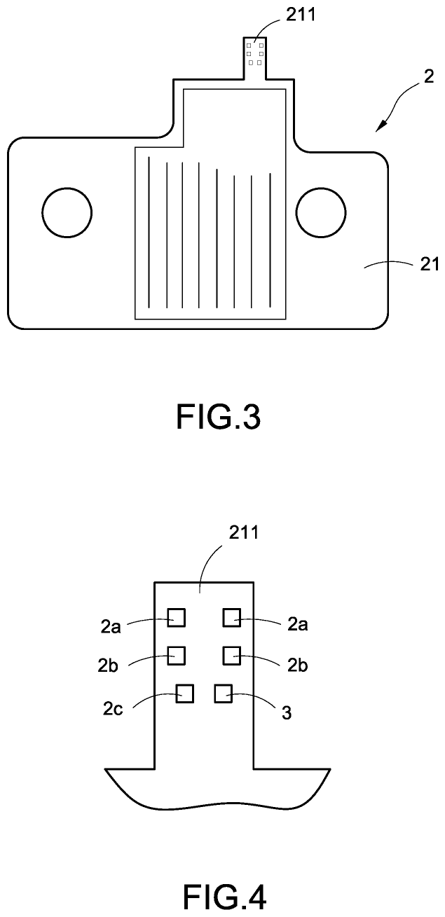

In the providing step S101, a temperature control structure is provided. The temperature control structure includes a microprocessor 1 and multiple micro sensors 2. The micro sensors 2 are flexible. The micro sensor 2, as shown in FIG. 3, includes a flexible sheet 21 and multiple micro sensing units (not labeled in FIG. 3) disposed on the flexible sheet 21. The flexible sheet 21 is a bendable and foldable thin flexible sheet, so it is adoptable for various non-flat or non-planar surfaces.

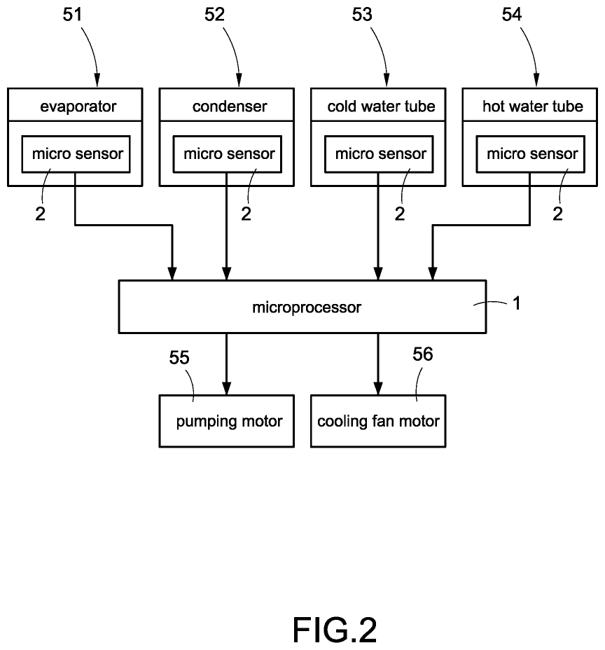

In the disposing step S103, the microprocessor 1 is disposed to the liquid cooling device. For example, the temperature control structure further includes a circuit board (not shown in figures). The microprocessor 1 is disposed on the circuit board. Thus, in the disposing step S103, the circuit board and the microprocessor 1 may be collectively disposed in the condenser 52 and isolated from the liquid in the condenser 52. The micro sensors 2, whose sizes are considerably small and thin, are disposed in the cold water tube 53 and the hot water tube 54 (as shown in FIG. 1A). In some embodiments, the micro sensors 2 are further disposed in the evaporator 51 and the condenser 52 (as shown in FIG. 1B). A width of the micro sensor 2 is less than a width of two fingers of an Asian adult man. As shown in FIG. 2, each micro sensor 2, the pumping motor 55 and the cooling fan motor 56 are connected to the microprocessor 1.

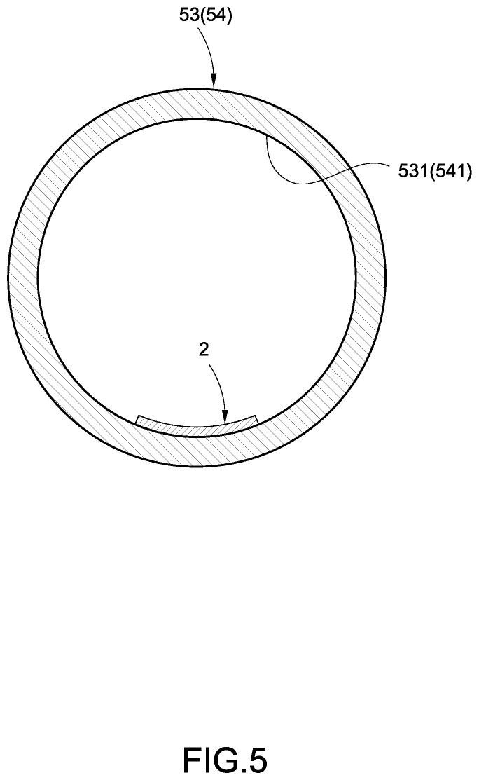

All inner walls of the evaporator 51, the condenser 52, the cold water tube 53 and the hot water tube 54 are non-flat or non-planar surfaces, but because the flexible sheet 21 of the micro sensor 2 is bendable and foldable, the flexible sheet 21 can be firmly adhered on the non-flat or non-planar inner walls. For example, as shown in FIG. 5, an inner wall 531 of the cold water tube 53 and an inner wall 541 of the hot water tube 54 are of an arc-shaped surface instead of a flat or planar surface, the micro sensor 2 may be adoptable to the arc-shape of the inner walls 531, 541 to be firmly adhered through the flexible sheet 21, so that the micro sensor 2 may directly contact with the heated liquid. As a result, the micro sensor 2 possesses the properties of high accuracy, high sensitivity and short response time. In addition, the micro sensor 2 may be further disposed in the evaporator 51 and the condenser 52 to make the micro sensor 2 be firmly adhered on a non-flat or non-planar surface in the evaporator 51 and the condenser 52 through the flexible sheet 21. Thus, the micro sensor 2 may directly contact with the heated liquid in the evaporator 51 and the condenser 52 or directly contact with the heated inner structure (the inner structure of the evaporator 51 and the condenser 52, not shown in the figures).

In the processing and controlling step S105, the microprocessor 1 receives actual data sensed in the cold water tube 53 and the hot water tube 54 by the micro sensors 2 to calculate after data is received as shown in FIG. 1A, or the microprocessor 1 receives actual data sensed in the evaporator 51, the condenser 52, the cold water tube 53 and the hot water tube 54 by the micro sensors 2 to calculate after data is received as shown in FIG. 1B. The microprocessor 1 controls the pumping motor 55 and the cooling fan motor 56 to modulate (adjust and change) the operating performance according to a calculated result. For example, the microprocessor 1 speeds up or slows down the rotation speed of the pumping motor 55 and the cooling fan motor 56, etc.

It is noted that the component used to receive and process (calculate) the sensed data in the disclosure is the microprocessor 1 disposed in the liquid cooling device. Therefore, the authority of the temperature control is changed from the CPU of the electronic product to the microprocessor 1 of the liquid cooling device. As a result, the design of a liquid cooling device may be completely and fully implemented by manufactures without being limited by the CPUs with different specifications.

In detail, as shown in FIGS. 3 and 4, the flexible sheet 21 is protruded with a sensing head 211. The size of the sensing head 211 is considerably smaller than that of the sheet body of the flexible sheet 21. All the micro sensing units are disposed and distributed on a side of the sensing head 211.

The micro sensing units includes at least one micro temperature sensing unit 2a, at least one micro voltage sensing unit 2b and at least one micro humidity sensing unit 2c. In other words, the micro sensor 2 may sense the temperature, the voltage and the humidity. In some embodiments, the micro sensor 2 further includes a micro heating unit 3 arranged correspondingly to at least one micro humidity sensing unit 2c. The micro heating unit 3 may shorten the response time of the micro humidity sensing unit 2c from 30 minutes to a few seconds.

While this disclosure has been described by means of specific embodiments, numerous modifications and variations could be made thereto by those skilled in the art without departing from the scope and spirit of this disclosure set forth in the claims.

What is claimed is:

1. A temperature controlling method of a liquid cooling device, used for cooling by a liquid, the temperature controlling method comprising:
providing a microprocessor and multiple micro sensors, wherein the micro sensors are flexible;
disposing the microprocessor on the liquid cooling device, wherein the liquid cooling device comprises an evaporator, a condenser, a cold water tube, a hot water tube, a pumping motor, and a cooling fan motor; and disposing each of the micro sensors in the cold water tube and the hot water tube respectively to directly contact with the liquid; and
by the microprocessor, receiving data sensed in the cold water tube and the hot water tube by each of the micro sensors to calculate, and controlling the pumping motor and the cooling fan motor to modulate an operating performance according to a calculated result.

2. The temperature controlling method of the liquid cooling device of claim 1, wherein each of the micro sensors is further disposed in the evaporator and the condenser, and the microprocessor receives data sensed in the evaporator, the condenser, the cold water tube and the hot water tube by the micro sensors to calculate.

3. The temperature controlling method of the liquid cooling device of claim 2, wherein each micro sensor is of a sheet shape and is adhered on a non-planar inner wall of the evaporator, the condenser, the cold water tube or the hot water tube.

4. The temperature controlling method of the liquid cooling device of claim 1, wherein each micro sensor comprises a flexible sheet and multiple micro sensing units, the flexible sheet comprises a sensing head protruding therefrom, the micro sensing units are disposed on a side of the sensing head.

5. The temperature controlling method of the liquid cooling device of claim 4, wherein the micro sensing units comprise at least one micro temperature sensing unit, at least one micro voltage sensing unit and at least one micro humidity sensing unit.

6. The temperature controlling method of the liquid cooling device of claim 5, wherein each micro sensor further comprises a micro heating unit arranged correspondingly to the at least one micro humidity sensing unit.
